(19) United States
(12) Patent Application Publication
(10) Pub. No.: US 2024/0310453 A1
(43) Pub. Date: Sep. 19, 2024

(54) HISTORY-AGNOSTIC BATTERY DEGRADATION INFERENCE

(71) Applicant: Toyota Research Institute, Inc., Los Altos, CA (US)

(72) Inventors: Mehrad Ansari, Rochester, NY (US); Shijing Sun, Mountain View, CA (US); Steven BJ Torrisi, Berkeley, CA (US); Amalie E. Trewartha, San Francisco, CA (US)

(73) Assignees: Toyota Research Institute, Inc., Los Altos, CA (US); Toyota Jidosha Kabushiki Kaisha, Toyota-shi Aichi-ken (JP)

(21) Appl. No.: 18/121,171

(22) Filed: Mar. 14, 2023

(51) Int. Cl. G01R 31/392; G01R 31/36; G01R 31/367

(52) U.S. Cl. CPC G01R 31/392; G01R 31/3648; G01R 31/367

(57) ABSTRACT

Systems, methods, and other embodiments described herein relate to an improved approach to determining battery state of health that is history agnostic. In one embodiment, a method includes acquiring a snippet of information about a battery. The method includes predicting, using a degradation model, attributes of a discharge capacity curve of the battery for successive future windows of time. The method includes generating a score according to the attributes to assess a state of health (SoH) of the battery. The method includes providing an indicator about the SoH of the battery when the score satisfies a threshold.

### TECHNICAL FIELD

The subject matter described herein relates, in general, to systems and methods for predicting battery degradation and, more particularly, to using a degradation model to determine when the discharge capacity curve encounters rapid nonlinear degradation.

### BACKGROUND

Batteries, such as lithium-ion batteries, are widely used in electric vehicles for energy storage. The performance of state-of-the-art lithium-ion batteries deteriorates with time and usage. Having accurate estimations of a state of health and being able to predict a future degradation rate is central when setting maintenance and warranty strategies. In particular, electric vehicle (EV) dealers and customers use this information to estimate the value of used EVs and determine second-life (e.g., grid storage) applications for used batteries. The state of health of a battery is generally dependent on the usage history. For example, two one-year-old batteries manufactured from the same production line, with one being fast-charged and discharged daily for a 20-mile trip and another only getting operated once a year for a one-hundred-mile trip, are expected to show very different rates of battery degradation.

In practice, a key challenge in battery performance prediction is that the comprehensive cycling history of a battery is not often available. However, available approaches for predicting battery state of health generally use a comprehensive history of battery information that includes both information across the life of the battery and the specific data itself, such as charging histories, temperature histories, discharge histories, and so on. As such, not only is the information for predicting the state of health extensive at each time step, but the information is also extensive across the history of the battery. As such, data storage and processing for such information can be burdensome when available, and when the information is not available, predicting the battery state of health can be infeasible or inaccurate.

### SUMMARY

In one embodiment, example systems and methods relate to an improved approach to determining battery state of health. As noted previously, predicting battery state of health can be a complex problem. In particular, because approaches to predicting the state of health rely significantly on large quantities of information that may be unavailable, accurately predicting the state of health can be problematic from multiple perspectives. That is, when the data is available, storage and computational costs can be significant, which may limit an ability to include such a system within a vehicle or other device associated with the battery. When the comprehensive data is unavailable, the accuracy of predictions may suffer, leading to unreliable results.

Therefore, in one embodiment, a history-agnostic approach is disclosed that relies on recent information about selected aspects of the battery to predict a state of health for a battery. For example, in one aspect, a disclosed system acquires snippets of information about a battery, which is in contrast to comprehensive battery information. The snippets may include data about a defined number of previous cycles of the battery, such as forty prior charge/discharge cycles, as opposed to a complete battery life history. The data can include, for example, current and voltage information output by the battery over the separate cycles. The system uses this information as input to a degradation model. The degradation model predicts attributes about the battery over successive future windows. The attributes generally characterize predicted operating aspects of the battery, such as a discharge capacity curve. From this prediction, the system scores the attributes and can assess whether the state of health of the battery is, for example, steadily decaying in a linear manner or experiencing a rapid nonlinear decline (i.e., reaching the inflection point of rapid nonlinear degradation). In this way, the disclosed approach improves predictions about the state of health of the battery in order to better maintain and manage the battery within various contexts, such as use within an electric vehicle.

In one embodiment, a degradation system is disclosed. The degradation system includes one or more processors and a memory communicably coupled to the one or more processors. The memory stores instructions that, when executed by the one or more processors, cause the one or more processors to acquire a snippet of information about a battery. The instructions cause the processor to predict, using a degradation model, attributes of a discharge capacity curve of the battery for successive future windows of time. The instructions cause the processor to generate a score according to the attributes to assess a state of health (SoH) of the battery. The instructions cause the processor to provide an indicator about the SoH of the battery when the score satisfies a threshold.

In one embodiment, a non-transitory computer-readable medium including instructions that, when executed by one or more processors, cause the one or more processors to perform various functions is disclosed. The instructions include instructions to acquire a snippet of information about a battery. The instructions include instructions to predict, using a degradation model, attributes of a discharge capacity curve of the battery for successive future windows of time. The instructions include instructions to generate a score according to the attributes to assess a state of health (SoH) of the battery. The instructions include instructions to provide an indicator about the SoH of the battery when the score satisfies a threshold.

In one embodiment, a method is disclosed. In one embodiment, the method includes acquiring a snippet of information about a battery. The method includes predicting, using a degradation model, attributes of a discharge capacity curve of the battery for successive future windows of time. The method includes generating a score according to the attributes to assess a state of health (SoH) of the battery. The method includes providing an indicator about the SoH of the battery when the score satisfies a threshold.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 illustrates one embodiment of a vehicle within which systems and methods disclosed herein may be implemented.

FIG. 2 illustrates one embodiment of a degradation system that is associated with a history-agnostic approach to determining the battery state of health (SoH).

FIG. 3 is a diagram illustrating the discharge capacity of a battery in relation to charge/discharge cycles.

FIG. 4 is a diagram that illustrates one embodiment of a degradation model.

FIG. 5 illustrates a diagram of a discharge capacity curve for which snippets of information are available and associated prediction windows.

FIG. 6 is a flowchart illustrating one embodiment of a method for determining the state of health (SoH) of a battery.

### DETAILED DESCRIPTION

Systems, methods, and other embodiments are disclosed associated with an improved approach to determining battery state of health. As noted previously, predicting battery state of health can be a complex problem. In particular, because approaches to predicting the state of health rely significantly on large quantities of information that may be unavailable, accurately predicting the state of health can be problematic from multiple perspectives. That is, when the data is available, storage and computational costs can be significant, which may limit an ability to include such a system within a vehicle or other device associated with the battery. When the comprehensive data is unavailable, the accuracy of predictions may suffer leading to unreliable results.

Therefore, in one embodiment, a history-agnostic approach is disclosed that relies on recent information about selected aspects of the battery to predict a state of health for a battery. For example, in one aspect, a disclosed system leverages a machine-learning framework that is capable of forecasting rates of capacity loss in a battery without having access to the full aging or manufacturing history of a battery. The presently disclosed system predicts the likelihood that a battery is about to undergo rapid nonlinear degradation, which precedes rapid linear degradation. In general, battery degradation tends to have three characteristic life stages or regimes that include an early linear regime where the loss in discharge capacity is slow and steady (e.g., well approximated by a straight line), a nonlinear regime where the loss in capacity accelerates (described as the inflection point or “knee point”), and a late linear regime where the loss is linear again, but declines much faster.

In various aspects, the machine-learning framework of the present system approximates the rate of falloff during various regimes over the life of a battery (e.g., the early and late linear regimes) to detect when the nonlinear regime is about to begin, which is the start of the battery degrading in quality at a faster rate than before. For example, in one aspect, a disclosed system acquires snippets of information about a battery, which is in contrast to comprehensive battery information. The snippets may include data about a defined number of previous cycles of the battery, such as forty prior charge/discharge cycles, as opposed to a complete battery life history. The data can include, for example, current and voltage information output by the battery over the separate cycles. The system uses this information as input to a degradation model. The degradation model predicts attributes about the battery over successive future windows. The attributes generally characterize predicted operating aspects of the battery, such as a discharge capacity. From this prediction, the system scores the attributes and can assess whether the state of health of the battery is, for example, stable or in decline (i.e., reaching the inflection point of rapid nonlinear degradation). In this way, the disclosed approach improves predictions about the state of health of the battery in order to better maintain and manage the battery within various contexts, such as use within an electric vehicle.

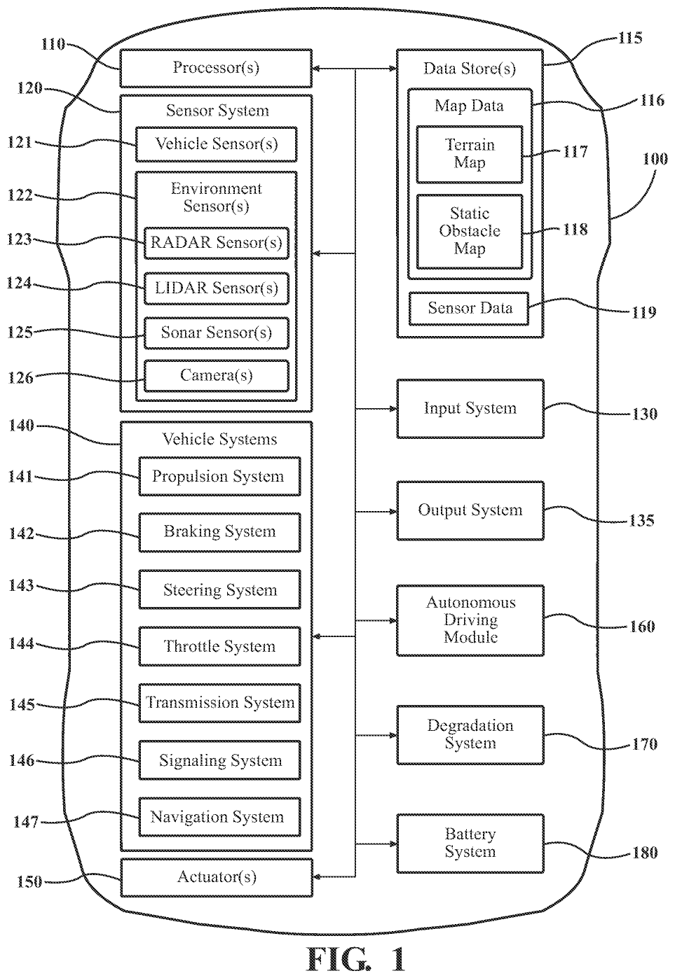

Referring to FIG. 1, an example of a vehicle 100 is illustrated. As used herein, a “vehicle” is any form of powered transport. In one or more implementations, the vehicle 100 is an automobile. While arrangements will be described herein with respect to electric vehicles, it will be understood that embodiments are not limited to electric vehicles. In some implementations, the vehicle 100 may be any electronic device (e.g., smartphone, surveillance camera, robot, etc.) that, for example, uses a battery to provide power, and thus benefits from the functionality discussed herein. In yet further embodiments, the disclosed degradation system 170 may be implemented separately from a battery and used to diagnose the state of health (SoH) for batteries according to provided information.

In any case, the vehicle 100 (or another electronic device) also includes various elements. It will be understood that, in various embodiments, it may not be necessary for the vehicle 100 to have all of the elements shown in FIG. 1. The vehicle 100 can have any combination of the various elements shown in FIG. 1. Further, the vehicle 100 can have additional elements to those shown in FIG. 1. In some arrangements, the vehicle 100 may be implemented without one or more of the elements shown in FIG. 1. While the various elements are illustrated as being located within the vehicle 100, it will be understood that one or more of these elements can be located external to the vehicle 100. Further, the elements shown may be physically separated by large distances and provided as remote services (e.g., cloud-computing services, software-as-a-service (SaaS), distributed computing service, etc.).

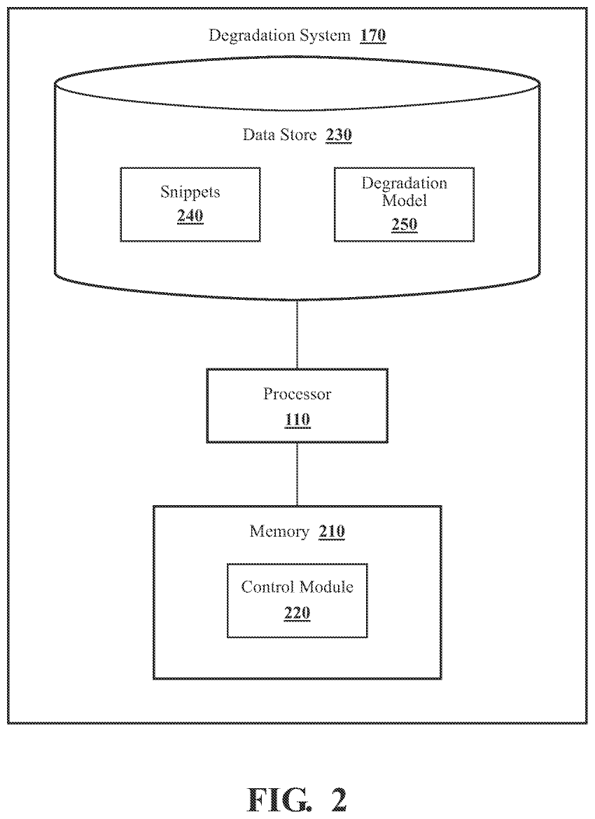

Some of the possible elements of the vehicle 100 are shown in FIG. 1 and will be described along with subsequent figures. However, a description of many of the elements in FIG. 1 will be provided after the discussion of FIGS. 2-6 for purposes of the brevity of this description. Additionally, it will be appreciated that for simplicity and clarity of illustration, where appropriate, reference numerals have been repeated among the different figures to indicate corresponding or analogous elements. In addition, the discussion outlines numerous specific details to provide a thorough understanding of the embodiments described herein. Those of skill in the art, however, will understand that the embodiments described herein may be practiced using various combinations of these elements.

In either case, the vehicle 100 includes a degradation system 170 that functions to predict the health of a battery according to a snippet of information about the battery. That is, instead of using an extensive history of the battery and to predict the state of health over future windows, the degradation system 170 leverages a limited set of information from prior N cycles of the battery. For example, in general, a battery system 180 monitors and controls the functioning (e.g., charging, discharging, etc.) of an internal battery that may be a Lithium-ion battery. As part of monitoring, the battery system 180 stores information about the operation of the battery. However, as noted previously, the information can be costly to maintain as the various data points can be numerous. Moreover, as the data storage is electronic, the information can become corrupted or may be lost. Thus, the degradation system 170 is configured to operate on limited data that does not capture a comprehensive history of the battery. Accordingly, it should be appreciated that while the degradation system 170 is described as being integrated along with a device that includes a particular battery, the degradation system 170 is capable of predicting battery health in a more robust manner than prior approaches, and thus may facilitate assessing batteries with which the degradation system 170 is not specifically linked other than to acquire the snippet information. The noted functions and methods will become more apparent with a further discussion of the figures.

With reference to FIG. 2, one embodiment of the degradation system 170 is further illustrated. The degradation system 170 is shown as including a processor 110. Accordingly, the processor 110 may be a part of the degradation system 170 or the degradation system 170 may access the processor 110 through a data bus or another communication path. In one or more embodiments, the processor 110 is an application-specific integrated circuit (ASIC) that is configured to implement functions associated with a control module 220. In general, the processor 110 is an electronic processor, such as a microprocessor, that is capable of performing various functions as described herein. In one embodiment, the degradation system 170 includes a memory 210 that stores the control module 220. The memory 210 is a random-access memory (RAM), read-only memory (ROM), a hard disk drive, a flash memory, or other suitable memory for storing the control module 220. The control module 220 is, for example, computer-readable instructions that, when executed by the processor 110, cause the processor 110 to perform the various functions disclosed herein. Of course, in various arrangements, the module 220 and/or other modules described herein may be hardware-based components, such as hardware controllers, system-on-a-chip (SoC), ASICs, and so on.

Furthermore, in one embodiment, the degradation system 170 includes a data store 230. The data store 230 is, in one embodiment, an electronic data structure, such as a database, that is stored in the memory 210 or another memory, and that is configured with routines that can be executed by the processor 110 for analyzing stored data, providing stored data, organizing stored data, and so on. Thus, in one embodiment, the data store 230 stores data used by the control module 220 in executing various functions. In one embodiment, the data store 230 includes snippets 240, and a degradation model 250 along with, for example, other information that is used by the control module 220.

The snippets 240, refer to information collected about the battery over prior cycles of the battery. The cycles are charge/discharge cycles that include, for example, a period of charging followed by a period of discharging. In general, the charge/discharge cycle can include discharging the battery of some capacity and charging the battery with added capacity. The values need not be the same nor extend to a whole capacity of the battery. In any case, the snippets 240 include values of, for example, voltage and current at an output of the battery over N prior cycles. Thus, the control module 220 may store the snippets 240 for the defined number of prior cycles N, while letting data prior to the N prior cycles expire. The N prior cycles can be selected per a particular implementation and may include, for example, 10 prior cycles of the battery. Moreover, while voltage and current are described, the snippets 240 may include further information in other implementations. In this way, the degradation system 170 functions to improve determinations about battery degradation/health without a need for acquiring and storing extensive information about the battery.

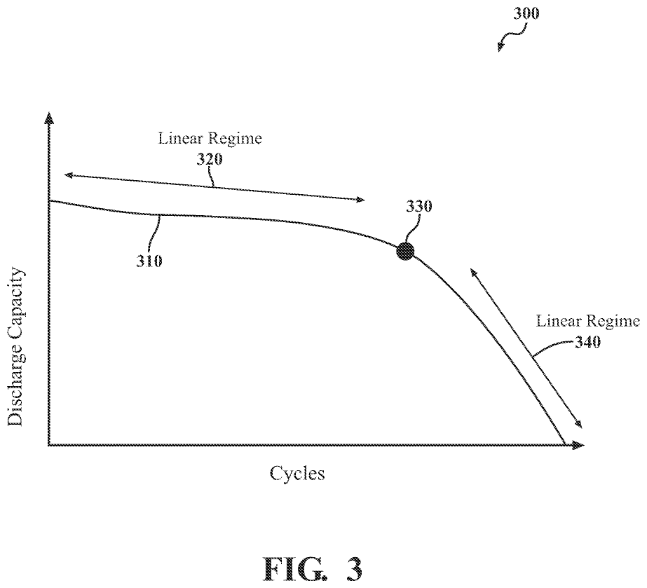

The snippets 240 characterize a discharge capacity of the battery at a given time and thus are generally indicative of a state of health for the battery at that time. By way of illustration, consider FIG. 3, which illustrates a graph 300 of a discharge capacity curve 310 over a life of a battery as represented by a number of cycles. As shown, early in the life of the battery, the degradation is generally stable and follows a linear regime 320, as illustrated by the linear fit to the curve over the first portion of cycles. However, once the battery ages to a certain point, the discharge capacity curve 310 experiences an inflection point 330 (also referred to as a knee point), which is when the battery undergoes rapid nonlinear degradation following the linear regime 320. This point represents a significant decline in the state of health of the battery after which the battery experiences another linear regime 340 of gradation that is more rapid than the first, as represented by the line with the greater negative slope. Thus, once the battery reaches the inflection point 330, the value/usefulness of the battery may be impacted, although the life of the battery can be extended if changes in the management of the battery are made, such as charging limits, and so on. Accordingly, identifying the inflection point 330 can provide a significant advantage when assessing the health of the battery and improving the longevity of the battery in operating the vehicle 100.

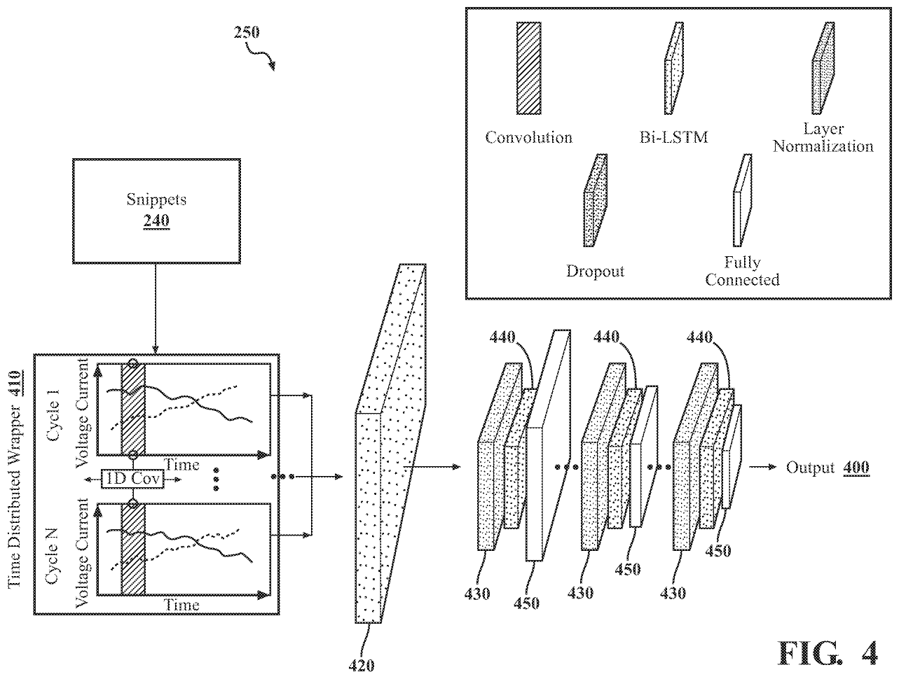

As such, the control module 220 implements the degradation model 250 to facilitate predicting the inflection point 330. FIG. 4 illustrates one embodiment of the degradation model 250 and how the degradation model 250 accepts the snippets 240 over a defined number of prior cycles N to produce an output 400. The degradation model 250 is, in at least one arrangement, a neural network, such as a recurrent neural network, that iteratively functions to predict a slope for a linear fit to the degradation curve of the battery over a future window of time that corresponds to future cycles of the battery that have not yet occurred. In general, the control module 220 controls the degradation model 250 to predict the slope for two successive future windows of time that include a near-term window and a mid-term window. The future windows have a defined width that can be, for example, preconfigured (e.g., 10 cycles each) or may be dynamically selected according to various conditions.

Accordingly, the degradation model 250 predicts the linearized magnitude of drop in the discharge capacity of the battery as measured by the slope of a linear fit to the discharge capacity curve, which the degradation model 250, in one approach, derives according to an end of the last cycle in the input window (i.e., from the snippets 240) and a mid-point of an output window. The slope is denoted as m₁ for the near-term window. Similarly, the degradation model 250 predicts a slope m₂ for the mid-term window according to, for example, the mid-point to a final cycle of the prediction window. With multiple slopes, the control module 220 is better able to account for changes in rates of degradation within the successive windows.

The slope m is derived from the linear relationship of a line defined as y=mx+b. In general, m will be a negative value as the battery degrades in capacity over time. However, the greater the magnitude (e.g., the extent of the negative slope) of m, the more severe falloff in capacity. Thus, overall, the slopes m₁ and m₂ are generally equal in the initial linear regime 320, and any disagreement with m₂ exceeding m₁ is generally indicative of the onset of the knee point and associated non-linearity. Thus, the degradation model 250 permits the control module 220 to infer battery degradation using recent cycle data with no prior knowledge of the degradation mechanism nor having access to the full cycle history.

Continuing with the architecture of the degradation model 250, as shown in FIG. 4, the degradation model 250 includes a convolutional neural network (CNN), which is described as the time-distributed wrapper 410, that processes each cycle within the snippets 240 provided as input. The wrapper 410 provides for correlating past and future data as learned by the CNN. The output of the wrapper 410 is provided to, in one arrangement, a bi-directional long short-term memory (Bi-LSTM) neural network 420. The Bi-LSTM NN 420 provides an output to a normalization layer 430 that feeds into a dropout layer 440 with a rate of, for example, 10%. The dropout layer is followed by a fully connected layer 450. This configuration is repeated three times until the final layer generates the output 400, which is a vector predicting the regressed values for the two slopes, m₁ and m₂, respectively.

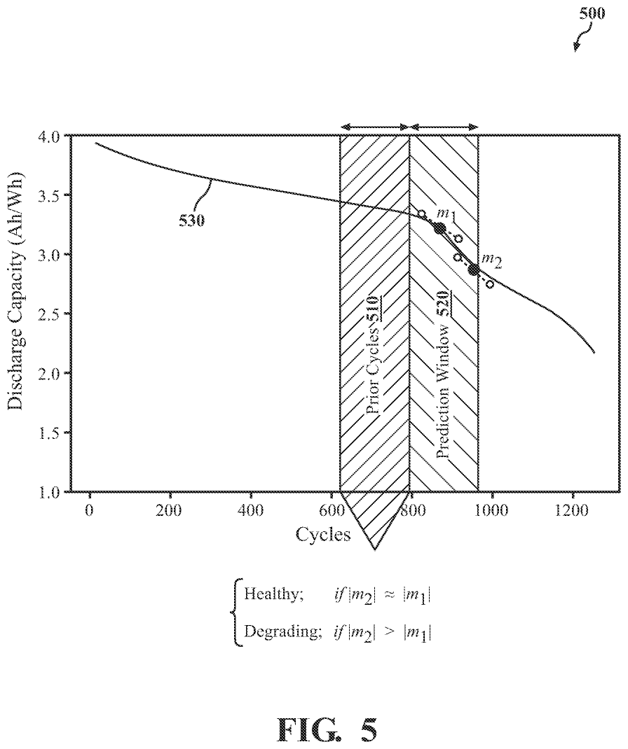

Accordingly, the control module 220 can then use the outputs 400 to determine whether the battery has encountered the knee point. As a further explanation of the outputs 400 and the determination of the knee point, consider FIG. 5. FIG. 5 illustrates a graph 500 of the discharge capacity of a battery in relation to discharge cycles. As shown, the only information that is available for input into the degradation model 250 are prior cycles 510, which are the snippets 240 in this example. The degradation model 250 uses the prior cycles 510 to predict the slopes m₁ and m₂ over the prediction window 520, which includes the near-term window and the mid-term window. As illustrated, a discharge capacity curve 530, which is unknown to the degradation system 170 other than for the prior cycles 510 and the predicted slopes of the prediction window 520, follows a general form as previously described in FIG. 3. It should be noted that the discharge capacity curve 530 is illustrated for purposes of reference and this information is not generally available to the degradation system 170, especially for any future cycles that have not yet occurred. Accordingly, the indicated slopes m₁ and m₂, as predicted by the model 250, are generally located around the knee point in the instant example.

As such, the control module 220 can compare the slopes m₁ and m₂ to determine whether the battery is approaching the knee point. When the values of m₁ and m₂ are substantially equivalent (e.g., within 1%), then the SoH for the battery is healthy, and use of the battery by the vehicle 100 may continue without adjustment. However, when m₂ is greater than m₁, then the battery has reached the knee point, and the state of health for the battery is reaching a region of rapid degradation. Therefore, the degradation system 170 may proceed with adapting the use of the battery in order to prolong battery life or at least provide an alert about a condition of the battery. As will be discussed further subsequently, the process of comparing m₁ and m₂ may involve using the values to score the health of the battery through a comparison of absolute values of the slopes from which various actions can be undertaken to adapt the operation of the vehicle 100 and the use of the battery. In this way, the degradation system 170 functions to improve the determination about the health of the battery and subsequent use of the battery.

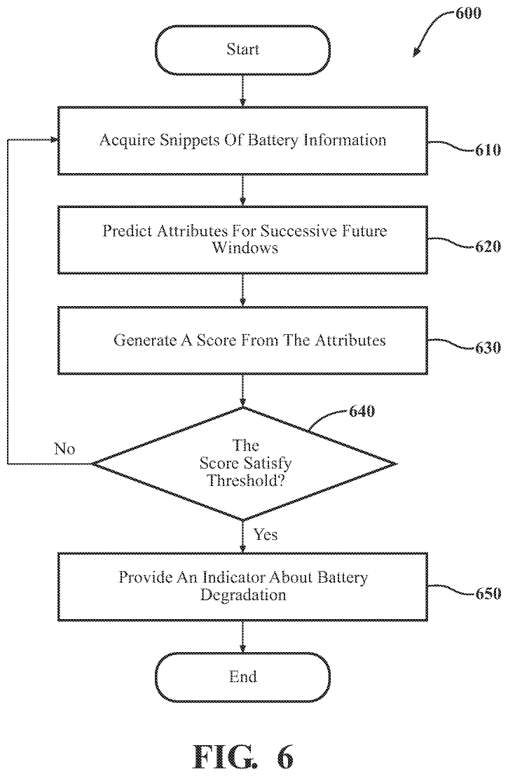

FIG. 6 illustrates a flowchart of a method 600 that is associated with predicting the state of health of a battery. Method 600 will be discussed from the perspective of the degradation system 170. While method 600 is discussed in combination with the degradation system 170, it should be appreciated that the method 600 is not limited to being implemented within the degradation system 170 but is instead one example of a system that may implement the method 600.

At 610, the control module 220 acquires a snippet 240 that is information about a battery. The snippet 240 includes, in at least one approach, voltage and current data over a defined number of prior cycles of the battery that is sensed at an output of the battery. The number of prior cycles of the battery may be dynamically selected according to, for example, an extent of information that is available. Otherwise, the control module 220 uses a predefined number of cycles. Moreover, the particular pieces of information that comprise the snippet 240 may vary according to implementation. For example, in further approaches, the snippet 240 may include different or added elements, such as readings at individual battery cells in a battery pack, internal resistances, temperatures, vehicle operating conditions, and so on. In any case, at least one advantage of the present approach is the history-agnostic nature of the approach that does not require extensive information about the battery and uses N predefined cycles, which may include, for example, 10, 25, 50, or another selection of cycles.

At 620, the control module 220 uses the degradation model 250 to predict attributes of a discharge capacity curve of the battery for successive future windows of time. In one approach, the control module 220 uses the degradation model 250 to analyze the snippet 240 and derive the attributes as representations of a linear fit to the discharge capacity curve. As previously outlined, because the character of the discharge capacity curve changes as the battery ages according to a number of cycles, the slope of each linear fit at the separate windows provides an accurate representation of the curve at those times. Therefore, the degradation model 250 includes a recurrent neural network that iterates over the snippet 240 to generate the slopes of the linear fit lines in order to assess whether the degradation is advancing. The future windows themselves are windows of cycles beyond a current cycle of the battery. For example, a near-term window can extend to ten cycles from a current time, while a mid-term window may extend from ten to twenty cycles into the future. Of course, the particular parameters of the windows may vary depending on implementation. In at least one approach, the future successive windows may be dynamically adaptable according to various conditions, such as the available number of prior cycles from which the predictions are derived.

At 630, the control module 220 generates a score for the attributes. In one configuration, the control module 220 determines a difference between the absolute values of the attributes predicted for the successive future windows. That is, because the slopes are expected to be negative, the control module 220 takes the absolute values and determines a difference between the absolute values in order to determine whether the slope of the mid-term window is greater than the slope of the near-term window. Because the knee point is an inflection in the curve where the slope becomes more severe, identifying an instance where the slope of the mid-term window is greater is generally indicative of the transition to the rapid linear degradation of the battery.

At 640, the control module 220 determines whether the SoH of the battery is encountering a knee point in the discharge capacity curve. In one approach, the control module 220 compares the score with a threshold that specifies when the slopes are substantially unequal. For example, the control module 220 may define the threshold as a difference of 1% of the values of the slopes. Of course, the particular threshold may be defined in relation to a particular implementation, but the threshold is defined in order to correlate the score with the knee point of the discharge capacity curve. Accordingly, if the score does not satisfy the threshold, then the control module 220 continues to monitor the battery and may generate an indicator that the battery is healthy, which can be used by the battery system 180 to maintain current operating characteristics. However, if the score does satisfy (e.g., meet or exceed) the threshold, then the control module 220 proceeds with additional actions as described subsequently.

At 650, responsive to the score satisfying the threshold, then control module 220 provides an indicator about the SoH of the battery. In general, the indicator specifies that the SoH of the battery is degrading, and the battery is not likely to remain in a healthy state where the discharge capacity remains generally consistent. Thus, the control module 220 uses the indicator, in at least one approach, to adapt the operation of the battery in relation to various aspects, such as altering the charging of the battery (e.g., charging voltages, durations, etc.), restricting charging capacity, restricting discharge, and so on. In general, the control module 220 may interact with the battery system 180 to cause the noted changes by, for example, communicating the indicator to the battery system 180 and/or providing a specific control signal. In any case, the degradation system 170 functions to improve monitoring and control of the battery through the improved assessment about the SoH of the battery.

FIG. 1 will now be discussed in full detail as an example environment within which the system and methods disclosed herein may operate. In some instances, the vehicle 100 is configured to switch selectively between an autonomous mode, one or more semi-autonomous operational modes, and/or a manual mode. “Manual mode” means that all of or a majority of the navigation and/or maneuvering of the vehicle 100 is performed according to inputs received from a user (e.g., human driver). In one or more arrangements, the vehicle 100 can be a conventional vehicle that is configured to operate in a manual mode.

In one or more embodiments, the vehicle 100 is an autonomous vehicle. As used herein, “autonomous vehicle” refers to a vehicle that operates in an autonomous mode. “Autonomous mode” refers to navigating and/or maneuvering the vehicle 100 along a travel route using one or more computing systems to control the vehicle 100 with minimal or no input from a human driver. In one or more embodiments, the vehicle 100 is highly automated or completely automated. In one embodiment, the vehicle 100 is configured with one or more semi-autonomous operational modes in which one or more computing systems perform a portion of the navigation and/or maneuvering of the vehicle along a travel route, and a vehicle operator (i.e., driver) provides inputs to the vehicle to perform a portion of the navigation and/or maneuvering of the vehicle 100 along a travel route.

The vehicle 100 can include one or more processors 110. In one or more arrangements, the processor(s) 110 can be a main processor of the vehicle 100. For instance, the processor(s) 110 can be an electronic control unit (ECU). The vehicle 100 can include one or more data stores 115 for storing one or more types of data. The data store 115 can include volatile and/or non-volatile memory. Examples of suitable data stores 115 include RAM (Random Access Memory), flash memory, ROM (Read Only Memory), PROM (Programmable Read-Only Memory), EPROM (Erasable Programmable Read-Only Memory), EEPROM (Electrically Erasable Programmable Read-Only Memory), registers, magnetic disks, optical disks, hard drives, or any other suitable storage medium, or any combination thereof. The data store 115 can be a component of the processor(s) 110, or the data store 115 can be operatively connected to the processor(s) 110 for use thereby. The term “operatively connected,” as used throughout this description, can include direct or indirect connections, including connections without direct physical contact.

In one or more arrangements, the one or more data stores 115 can include map data 116. The map data 116 can include maps of one or more geographic areas. In some instances, the map data 116 can include information or data on roads, traffic control devices, road markings, structures, features, and/or landmarks in the one or more geographic areas. The map data 116 can be in any suitable form. In some instances, the map data 116 can include aerial views of an area. In some instances, the map data 116 can include ground views of an area, including 360-degree ground views. The map data 116 can include measurements, dimensions, distances, and/or information for one or more items included in the map data 116 and/or relative to other items included in the map data 116. The map data 116 can include a digital map with information about road geometry. The map data 116 can be high quality and/or highly detailed.

In one or more arrangements, the map data 116 can include one or more terrain maps 117. The terrain map(s) 117 can include information about the ground, terrain, roads, surfaces, and/or other features of one or more geographic areas. The terrain map(s) 117 can include elevation data in the one or more geographic areas. The map data 116 can be high quality and/or highly detailed. The terrain map(s) 117 can define one or more ground surfaces, which can include paved roads, unpaved roads, land, and other things that define a ground surface.

In one or more arrangements, the map data 116 can include one or more static obstacle maps 118. The static obstacle map(s) 118 can include information about one or more static obstacles located within one or more geographic areas. A “static obstacle” is a physical object whose position does not change or substantially change over a period of time and/or whose size does not change or substantially change over a period of time. Examples of static obstacles include trees, buildings, curbs, fences, railings, medians, utility poles, statues, monuments, signs, benches, furniture, mailboxes, large rocks, hills. The static obstacles can be objects that extend above ground level. The one or more static obstacles included in the static obstacle map(s) 118 can have location data, size data, dimension data, material data, and/or other data associated with it. The static obstacle map(s) 118 can include measurements, dimensions, distances, and/or information for one or more static obstacles. The static obstacle map(s) 118 can be high quality and/or highly detailed. The static obstacle map(s) 118 can be updated to reflect changes within a mapped area.

The one or more data stores 115 can include sensor data 119. In this context, “sensor data” means any information about the sensors that the vehicle 100 is equipped with, including the capabilities and other information about such sensors. As will be explained below, the vehicle 100 can include the sensor system 120. The sensor data 119 can relate to one or more sensors of the sensor system 120. As an example, in one or more arrangements, the sensor data 119 can include information on one or more LIDAR sensors 124 of the sensor system 120.

In some instances, at least a portion of the map data 116 and/or the sensor data 119 can be located in one or more data stores 115 located onboard the vehicle 100. Alternatively, or in addition, at least a portion of the map data 116 and/or the sensor data 119 can be located in one or more data stores 115 that are located remotely from the vehicle 100.

As noted above, the vehicle 100 can include the sensor system 120. The sensor system 120 can include one or more sensors. “Sensor” means any device, component, and/or system that can detect, and/or sense something. The one or more sensors can be configured to detect, and/or sense in real-time. As used herein, the term “real-time” means a level of processing responsiveness that a user or system senses as sufficiently immediate for a particular process or determination to be made, or that enables the processor to keep up with some external process.

In arrangements in which the sensor system 120 includes a plurality of sensors, the sensors can work independently from each other. Alternatively, two or more of the sensors can work in combination with each other. In such a case, the two or more sensors can form a sensor network. The sensor system 120 and/or the one or more sensors can be operatively connected to the processor(s) 110, the data store(s) 115, and/or another element of the vehicle 100 (including any of the elements shown in FIG. 1). The sensor system 120 can acquire data of at least a portion of the external environment of the vehicle 100.

The sensor system 120 can include any suitable type of sensor. Various examples of different types of sensors will be described herein. However, it will be understood that the embodiments are not limited to the particular sensors described. The sensor system 120 can include one or more vehicle sensors 121. The vehicle sensor(s) 121 can detect, determine, and/or sense information about the vehicle 100 itself. In one or more arrangements, the vehicle sensor(s) 121 can be configured to detect, and/or sense position and orientation changes of the vehicle 100, such as, for example, based on inertial acceleration. In one or more arrangements, the vehicle sensor(s) 121 can include one or more accelerometers, one or more gyroscopes, an inertial measurement unit (IMU), a dead-reckoning system, a global navigation satellite system (GNSS), a global positioning system (GPS), a navigation system 147, and/or other suitable sensors. The vehicle sensor(s) 121 can be configured to detect, and/or sense one or more characteristics of the vehicle 100. In one or more arrangements, the vehicle sensor(s) 121 can include a speedometer to determine a current speed of the vehicle 100.

Alternatively, or in addition, the sensor system 120 can include one or more environment sensors 122 configured to acquire, and/or sense driving environment data. “Driving environment data” includes data or information about the external environment in which an autonomous vehicle is located or one or more portions thereof. For example, the one or more environment sensors 122 can be configured to detect, quantify and/or sense obstacles in at least a portion of the external environment of the vehicle 100 and/or information/data about such obstacles. Such obstacles may be stationary objects and/or dynamic objects. The one or more environment sensors 122 can be configured to detect, measure, quantify and/or sense other things in the external environment of the vehicle 100, such as, for example, lane markers, signs, traffic lights, traffic signs, lane lines, crosswalks, curbs proximate the vehicle 100, off-road objects, etc.

Various examples of sensors of the sensor system 120 will be described herein. The example sensors may be part of the one or more environment sensors 122 and/or the one or more vehicle sensors 121. However, it will be understood that the embodiments are not limited to the particular sensors described.

As an example, in one or more arrangements, the sensor system 120 can include one or more radar sensors 123, one or more LIDAR sensors 124 (e.g., 4 beam LiDAR), one or more sonar sensors 125, and/or one or more cameras 126. In one or more arrangements, the one or more cameras 126 can be high dynamic range (HDR) cameras or infrared (IR) cameras.

The vehicle 100 can include an input system 130. An “input system” includes any device, component, system, element or arrangement or groups thereof that enable information/data to be entered into a machine. The input system 130 can receive an input from a vehicle passenger (e.g., a driver or a passenger). The vehicle 100 can include an output system 135. An “output system” includes a device, or component, that enables information/data to be presented to a vehicle passenger (e.g., a person, a vehicle passenger, etc.).

The vehicle 100 can include one or more vehicle systems 140. Various examples of the one or more vehicle systems 140 are shown in FIG. 1. However, the vehicle 100 can include more, fewer, or different vehicle systems. It should be appreciated that although particular vehicle systems are separately defined, each or any of the systems or portions thereof may be otherwise combined or segregated via hardware and/or software within the vehicle 100. The vehicle 100 can include a propulsion system 141, a braking system 142, a steering system 143, throttle system 144, a transmission system 145, a signaling system 146, and/or a navigation system 147. Each of these systems can include one or more devices, components, and/or a combination thereof, now known or later developed.

The navigation system 147 can include one or more devices, applications, and/or combinations thereof, now known or later developed, configured to determine the geographic location of the vehicle 100 and/or to determine a travel route for the vehicle 100. The navigation system 147 can include one or more mapping applications to determine a travel route for the vehicle 100. The navigation system 147 can include a global positioning system, a local positioning system, or a geolocation system.

The processor(s) 110, the degradation system 170, and/or the automated driving module 160 can be operatively connected to communicate with the various vehicle systems 140 and/or individual components thereof. For example, returning to FIG. 1, the processor(s) 110 and/or the automated driving module 160 can be in communication to send and/or receive information from the various vehicle systems 140 to control the movement, speed, maneuvering, heading, direction, etc. of the vehicle 100. The processor(s) 110, the degradation system 170, and/or the automated driving module 160 may control some or all of these vehicle systems 140 and, thus, may be partially or fully autonomous.

The processor(s) 110, the degradation system 170, and/or the automated driving module 160 can be operatively connected to communicate with the various vehicle systems 140 and/or individual components thereof. For example, returning to FIG. 1, the processor(s) 110, the degradation system 170, and/or the automated driving module 160 can be in communication to send and/or receive information from the various vehicle systems 140 to control the movement, speed, maneuvering, heading, direction, etc. of the vehicle 100. The processor(s) 110, the degradation system 170, and/or the automated driving module 160 may control some or all of these vehicle systems 140.

The processor(s) 110, the degradation system 170, and/or the automated driving module 160 may be operable to control the navigation and/or maneuvering of the vehicle 100 by controlling one or more of the vehicle systems 140 and/or components thereof. For instance, when operating in an autonomous mode, the processor(s) 110, the degradation system 170, and/or the automated driving module 160 can control the direction and/or speed of the vehicle 100. The processor(s) 110, the degradation system 170, and/or the automated driving module 160 can cause the vehicle 100 to accelerate (e.g., by increasing the supply of energy), decelerate (e.g., by applying brakes) and/or change direction (e.g., by turning the front two wheels). As used herein, “cause” or “causing” means to make, force, compel, direct, command, instruct, and/or enable an event or action to occur or at least be in a state where such event or action may occur, either in a direct or indirect manner.

The vehicle 100 can include one or more actuators 150. The actuators 150 can be an element or combination of elements operable to modify, adjust and/or alter one or more of the vehicle systems 140 or components thereof responsive to receiving signals or other inputs from the processor(s) 110 and/or the automated driving module 160. Any suitable actuator can be used. For instance, the one or more actuators 150 can include motors, pneumatic actuators, hydraulic pistons, relays, solenoids, and/or piezoelectric actuators, just to name a few possibilities.

The vehicle 100 can include one or more modules, at least some of which are described herein. The modules can be implemented as computer-readable program code that, when executed by a processor 110, implement one or more of the various processes described herein. One or more of the modules can be a component of the processor(s) 110, or one or more of the modules can be executed on and/or distributed among other processing systems to which the processor(s) 110 is operatively connected. The modules can include instructions (e.g., program logic) executable by one or more processor(s) 110. Alternatively, or in addition, one or more data store 115 may contain such instructions.

In one or more arrangements, one or more of the modules described herein can include artificial or computational intelligence elements, e.g., neural network, fuzzy logic, or other machine learning algorithms. Further, in one or more arrangements, one or more of the modules can be distributed among a plurality of the modules described herein. In one or more arrangements, two or more of the modules described herein can be combined into a single module.

The vehicle 100 can include one or more automated driving modules 160. The automated driving module 160 can be configured to receive data from the sensor system 120 and/or any other type of system capable of capturing information relating to the vehicle 100 and/or the external environment of the vehicle 100. In one or more arrangements, the automated driving module 160 can use such data to generate one or more driving scene models. The automated driving module 160 can determine a position and velocity of the vehicle 100. The automated driving module 160 can determine the location of obstacles, obstacles, or other environmental features including traffic signs, trees, shrubs, neighboring vehicles, pedestrians, etc.

The automated driving module 160 can be configured to receive, and/or determine location information for obstacles within the external environment of the vehicle 100 for use by the processor(s) 110, and/or one or more of the modules described herein to estimate position and orientation of the vehicle 100, vehicle position in global coordinates based on signals from a plurality of satellites, or any other data and/or signals that could be used to determine the current state of the vehicle 100 or determine the position of the vehicle 100 with respect to its environment for use in either creating a map or determining the position of the vehicle 100 in respect to map data.

The automated driving module 160 either independently or in combination with the degradation system 170 can be configured to determine travel path(s), current autonomous driving maneuvers for the vehicle 100, future autonomous driving maneuvers and/or modifications to current autonomous driving maneuvers based on data acquired by the sensor system 120, driving scene models, and/or data from any other suitable source. “Driving maneuver” means one or more actions that affect the movement of a vehicle. Examples of driving maneuvers include: accelerating, decelerating, braking, turning, moving in a lateral direction of the vehicle 100, changing travel lanes, merging into a travel lane, and/or reversing, just to name a few possibilities. The automated driving module 160 can be configured to implement determined driving maneuvers. The automated driving module 160 can cause, directly or indirectly, such autonomous driving maneuvers to be implemented. As used herein, “cause” or “causing” means to make, command, instruct, and/or enable an event or action to occur or at least be in a state where such event or action may occur, either in a direct or indirect manner. The automated driving module 160 can be configured to execute various vehicle functions and/or to transmit data to, receive data from, interact with, and/or control the vehicle 100 or one or more systems thereof (e.g., one or more of vehicle systems 140).

Detailed embodiments are disclosed herein. However, it is to be understood that the disclosed embodiments are intended only as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in FIGS. 1-6, but the embodiments are not limited to the illustrated structure or application.

The flowcharts and block diagrams in the Figures illustrate the architecture, functionality, and operation of possible implementations of systems, methods, and computer program products according to various embodiments. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components and/or processes described above can be realized in hardware or a combination of hardware and software and can be realized in a centralized fashion in one processing system or in a distributed fashion where different elements are spread across several interconnected processing systems. Any kind of processing system or another apparatus adapted for carrying out the methods described herein is suited. A typical combination of hardware and software can be a processing system with computer-usable program code that, when being loaded and executed, controls the processing system such that it carries out the methods described herein. The systems, components and/or processes also can be embedded in a computer-readable storage, such as a computer program product or other data programs storage device, readable by a machine, tangibly embodying a program of instructions executable by the machine to perform methods and processes described herein. These elements also can be embedded in an application product which comprises all the features enabling the implementation of the methods described herein and, which when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: a portable computer diskette, a hard disk drive (HDD), a solid-state drive (SSD), a read-only memory (ROM), an erasable programmable read-only memory (EPROM or Flash memory), a portable compact disc read-only memory (CD-ROM), a digital versatile disc (DVD), an optical storage device, a magnetic storage device, or any suitable combination of the foregoing. In the context of this document, a computer-readable storage medium may be any tangible medium that can contain, or store a program for use by or in connection with an instruction execution system, apparatus, or device.

Generally, module, as used herein, includes routines, programs, objects, components, data structures, and so on that perform particular tasks or implement particular data types. In further aspects, a memory generally stores the noted modules. The memory associated with a module may be a buffer or cache embedded within a processor, a RAM, a ROM, a flash memory, or another suitable electronic storage medium. In still further aspects, a module as envisioned by the present disclosure is implemented as an application-specific integrated circuit (ASIC), a hardware component of a system on a chip (SoC), as a programmable logic array (PLA), or as another suitable hardware component that is embedded with a defined configuration set (e.g., instructions) for performing the disclosed functions.

Program code embodied on a computer-readable medium may be transmitted using any appropriate medium, including but not limited to wireless, wireline, optical fiber, cable, RF, etc., or any suitable combination of the foregoing. Computer program code for carrying out operations for aspects of the present arrangements may be written in any combination of one or more programming languages, including an object-oriented programming language such as Java™, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all possible combinations of one or more of the associated listed items. As an example, the phrase “at least one of A, B, and C” includes A only, B only, C only, or any combination thereof (e.g., AB, AC, BC or ABC).

Aspects herein can be embodied in other forms without departing from the spirit or essential attributes thereof. Accordingly, reference should be made to the following claims, rather than to the foregoing specification, as indicating the scope hereof.

What is claimed is:

1. A degradation system, comprising:
one or more processors;
a memory communicably coupled to the one or more processors and storing instructions that, when executed by the one or more processors, cause the one or more processors to:
acquire a snippet of information about a battery;
predict, using a degradation model, attributes of a discharge capacity curve of the battery for successive future windows of time;
generate a score according to the attributes to assess a state of health (SoH) of the battery; and
provide an indicator about the SoH of the battery when the score satisfies a threshold.

2. The degradation system of claim 1, wherein the instructions to predict the attributes include instructions to predict a slope for a linear fit to the discharge capacity curve at each of the successive future windows, and wherein the successive future windows include future cycles of the battery over a near-term window and a mid-term window.

3. The degradation system of claim 1, wherein the instructions to generate the score include instructions to determine a difference between the attributes predicted for the successive future windows.

4. The degradation system of claim 1, wherein the instructions further include instructions to determine whether the SoH of the battery is encountering a knee point in the discharge capacity curve by comparing the score with the threshold that specifies when the attributes are substantially unequal, the knee point indicating an inflection point in the discharge capacity curve where the battery is about to undergo rapid nonlinear degradation.

5. The degradation system of claim 1, wherein the instructions to provide the indicator include instructions to adapt operation of the battery in relation to at least one of altering charging of the battery, and restricting charging capacity.

6. The degradation system of claim 1, wherein the instructions to predict the attributes include instructions to iteratively apply that degradation model that is a recurrent neural network (RNN).

7. The degradation system of claim 1, wherein the snippet includes voltage and current over a defined number of prior cycles of the battery, the prior cycles being charge-discharge cycles.

8. The degradation system of claim 1, wherein the degradation system is integrated within an electric vehicle to monitor the battery.

9. A non-transitory computer-readable medium including instructions that, when executed by one or more processors, cause the one or more processors to:
acquire a snippet of information about a battery;
predict, using a degradation model, attributes of a discharge capacity curve of the battery for successive future windows of time;
generate a score according to the attributes to assess a state of health (SoH) of the battery; and
provide an indicator about the SoH of the battery when the score satisfies a threshold.

10. The non-transitory computer-readable medium of claim 9, wherein the instructions to predict the attributes include instructions to predict a slope for a linear fit to the discharge capacity curve at each of the successive future windows, and wherein the successive future windows include future cycles of the battery over a near-term window and a mid-term window.

11. The non-transitory computer-readable medium of claim 9, wherein the instructions to generate the score include instructions to determine a difference between the attributes predicted for the successive future windows.

12. The non-transitory computer-readable medium of claim 9, wherein the instructions further include instructions to determine whether the SoH of the battery is encountering a knee point in the discharge capacity curve by comparing the score with the threshold that specifies when the attributes are substantially unequal, the knee point indicating an inflection point in the discharge capacity curve where the battery is about to undergo rapid nonlinear degradation.

13. The non-transitory computer-readable medium of claim 9, wherein the instructions to provide the indicator include instructions to adapt operation of the battery in relation to at least one of altering charging of the battery, and restricting charging capacity.

14. A method, comprising:
acquiring a snippet of information about a battery;
predicting, using a degradation model, attributes of a discharge capacity curve of the battery for successive future windows of time;
generating a score according to the attributes to assess a state of health (SoH) of the battery; and
providing an indicator about the SoH of the battery when the score satisfies a threshold.

15. The method of claim 14, wherein predicting the attributes includes predicting a slope for a linear fit to the discharge capacity curve at each of the successive future windows, and wherein the successive future windows include future cycles of the battery over a near-term window and a mid-term window.

16. The method of claim 14, wherein generating the score includes determining a difference between the attributes predicted for the successive future windows.

17. The method of claim 14, further comprising:
determining whether the SoH of the battery is encountering a knee point in the discharge capacity curve by comparing the score with the threshold that specifies when the attributes are substantially unequal, the knee point indicating an inflection point in the discharge capacity curve where the battery is about to undergo rapid nonlinear degradation.

18. The method of claim 14, wherein providing the indicator includes adapting operation of the battery in relation to at least one of altering charging of the battery, and restricting charging capacity.

19. The method of claim 14, wherein predicting the attributes includes iteratively applying that degradation model that is a recurrent neural network (RNN) to the snippet.

20. The method of claim 14, wherein the snippet includes voltage and current over a defined number of prior cycles of the battery, the prior cycles being charge-discharge cycles.
